(19) United States
(12) Patent Application Publication
(10) Pub. No.: US 2014/0199518 A1
(43) Pub. Date: Jul. 17, 2014

(54) Facile Large Area Periodic Sub-Micron Photolithography

(71) Applicant: Arizona Board of Regents acting for and on behalf of Arizona State University, Scottsdale, AZ (US)

(72) Inventors: Hongbin Yu, Chandler, AZ (US); Hanqing Jiang, Chandler, AZ (US); Kevin Chen, Hillsboro, OR (US); Ebraheem Ali Azhar, Phoenix, AZ (US); Teng Ma, Tempe, AZ (US)

(21) Appl. No.: 14/081,466

(22) Filed: Nov. 15, 2013

Related U.S. Application Data
(60) Provisional application No. 61/726,773, filed on Nov. 15, 2012.

(51) Int. Cl. G03F 7/09

(52) U.S. Cl. CPC G03F 7/09
USPC 428/152; 430/270.1; 430/322; 430/325

(57) ABSTRACT

Disclosed herein are articles and methods useful for the lithographic applications. The articles comprise a wrinkling structure and a photosensitive material. The articles and methods provide low cost alternatives to conventional lithographic applications. This abstract is intended as a scanning tool for purposes of searching in the particular art and is not intended to be limiting of the present invention.

### CROSS-REFERENCE TO RELATED APPLICATIONS

This Application claims the benefit of U.S. Provisional Application No. 61/726,773, filed on Nov. 15, 2012, which is incorporated herein by reference in its entirety.

### STATEMENT OF GOVERNMENT SUPPORT

This invention was made with government support under grant numbers ECCS-0926017 and CMMI-0700440, both awarded by the National Science Foundation. The government has certain rights in the invention.

### BACKGROUND

Sub-micron periodic patterns are heavily utilized in several applications, including memory, biological devices, optoelectronics, and solar cells based on nanostructures. Although techniques capable of fabricating sub-micron features have been developed and are well understood, including electron beam lithography (EBL), deep ultraviolet (UV) and interference lithography, scanning probe microscope (SPM) lithography, nanoimprint lithography, and self-assembly, these techniques offer their own set of prohibitive challenges. For example, EBL, deep UV lithography, and interference lithography require expensive equipment, while methods such as SPM lithography, along with EBL, have a serial write mechanism that makes large-area patterning costly and time-consuming. While nanoimprint lithography and self-assembly are relatively low cost and parallel processes, both still require an initial sub-micron patterning technique as described above, to create a master mold or masking pattern.

Accordingly, described herein are articles and methods related to cheap and reproducible lithographic techniques.

### SUMMARY OF THE INVENTION

In accordance with the purpose(s) of the invention, as embodied and broadly described herein, this disclosure, in one aspect, relates to fabrication techniques for producing periodic sub-micron structures, and specifically to fabrication techniques for producing periodic structures over large areas utilizing wrinkling structures.

The present disclosure relates to fabrication techniques for producing periodic sub-micron structures, and specifically to fabrication techniques for producing periodic structures over large areas utilizing a polymer mask.

Disclosed herein are articles comprising a wrinkling structure and a film of photosensitive material, wherein the wrinkling structure comprises a soft substrate and a first material, wherein the wrinkling structure has a first side and a second side, wherein at least a portion of the first side of the wrinkling structure contact at least a portion of the film of the photosensitive material.

Also disclosed herein is a method comprising a) providing article comprising a wrinkling structure and a film photosensitive material, wherein the wrinkling structure comprises a soft substrate and a first material, wherein the wrinkling structure has a first side and a second side, wherein the film photosensitive material has a first and second side, wherein at least a portion of the first side of the wrinkling structure contact at least a portion of the first side of the film of the photosensitive material; and irradiating second side of the wrinkling structure, thereby causing a chemical reaction in at least a portion of the photosensitive material.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### BRIEF DESCRIPTION OF THE FIGURES

The accompanying figures, which are incorporated in and constitute a part of this specification, illustrate several aspects and together with the description serve to explain the principles of the invention.

FIG. 1 shows: (a) a schematic of the fabrication process for a PDMS/Au grating, (b) Optical microscopy image and (c) Atomic Force Microscopy (AFM) image of wrinkling profile of PDMS/Au grating surface. (d) Scanning Electrom Microscopy (SEM) image of wrinkles. (e) Wrinkling wavelength (period) distribution at ten different spots over a surface area of 100×100 μm². The wrinkling period remains largely constant over this surface area, in good agreement with the calculated period value by Eq. (1). The error bars are one standard deviation of the data, which is taken as the experimental uncertainty of the measurement.

FIG. 2 shows: (a) an optical image of a PDMS mask, and (b) a zoomed-in scanning electron micrograph of the sinusoidal pattern on the PDMS mask.

FIG. 3A shows a schematic of a pattern transfer process from a PDMS buckled mask to a photoresist-coated substrate. FIG. 3B shows the pattern of the photoresist after development.

FIG. 4A-4D show various periodic patterns that can be transferred to a photoresist layer through a PDMS mask: (a) image of line grating pattern transferred to glass; (b) rectangular pillar pattern fabricated through two exposures at 60 mJ per exposure; (c) nanowell pattern fabricated through two exposures at 40 mJ per exposure; and (d) optical image of a mask fabricated using oxygen plasma rather than Au/Pd deposition.

FIG. 5 shows the optical setup used in the micro-strain sensing.

FIGS. 6A and 6B shows (a) Schematic of PDMS grating attached on silicon substrate. (b) Strain contours in the horizontal direction for different ratios of PDMS lengths (L) and a constant thickness (h=100 μm).

FIGS. 7A and 7B shows (a) ε_{pdms}/ε_{Si} and ε_{pdms} as a function of L/h and (b) a phase diagram of ε_{pdms}/ε_{Si}.

FIG. 8A-8C show diffracted beam intensity simulations based on the multi-slit grating model shown in (a), with grating to screen distance L=10 cm. Small variations are applied to the grating periodicity to obtain the peak shift, as illustrated in (b) and (c). Spot size is 200 μm (or number of slits N=240) in (b), and 50 μm (or N=60) in (c).

FIG. 9A-9C show measured CTE results for (a) freestanding PDMS, (b) Cu and (c) Si. Insets are the schematics of the setup for thermal micro-strain measurement.

FIG. 10 shows a directly fabricated grating on a rough Cu surface.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### Description

### A. Definitions

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

All publications mentioned herein are incorporated herein by reference to disclose and describe the methods and/or materials in connection with which the publications are cited.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, example methods and materials are now described.

As used in the specification and the appended claims, the singular forms “a,” “an” and “the” include plural referents unless the context clearly dictates otherwise. Thus, for example, reference to “a material” includes mixtures of two or more such materials, and the like.

Ranges can be expressed herein as from “about” one particular value, and/or to “about” another particular value. When such a range is expressed, a further aspect includes from the one particular value and/or to the other particular value. Similarly, when values are expressed as approximations, by use of the antecedent “about,” it will be understood that the particular value forms a further aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

As used herein, the terms “optional” or “optionally” means that the subsequently described event or circumstance can or cannot occur, and that the description includes instances where said event or circumstance occurs and instances where it does not.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

The term “contacting” as used herein refers to bringing two materials together so the physically or chemically interact with each other. For example contacting a first side of a wrinkling structure with a film of photosensitive material can refer to that the first side of the wrinkling structure and the film of photosensitive material physically interact or contact each other.

The term “etchable substrate” as used herein refers to a material that can be etched via dry and/or wet etch processes. Examples of such processes include plasma etching, such as reactive-ion-etching (RIE) and inductively coupled plasma etching (ICP). Etchable substrates include, but are not limited to aluminum, Indium tin oxide, chromium, gallium arsenide, gold, molybdenum, platinum, silicon, silicon dioxide, silicon nitride, titanium, Titanium nitride, tungsten, and polymers substrates, such as, polyimide PDMS. For example, an etchable substrate can be silicon or silicon dioxide.

### B. Articles

Wrinkling (or buckling) is a commonly observed mechanical instability phenomenon typically treated as a nuisance. In recent years, researchers have proposed the use of ordered wrinkling structures of stiff thin films on soft substrates with wavelengths in the nanometer to micrometer order, in a broad spectrum of applications, such as, microfluidic devices [1], templates for cell guidance [2, 3] and colloidal particles assembly [4, 5], stretchable electronic interconnects [6-11], stretchable electronic devices [12-18], modern metrology methods [19], tunable diffraction and phase gratings [1, 2, 20, 21], and methods for micro/nano-fabrication [22-25].

A method of fabricating large area periodic submicron structures is called soft contact optical lithography and has been explored recently. In this method, a polymer mask with a relief pattern is used to replace the traditional glass mask in photolithography. When light is exposed through the polymer mask onto the photoresist, there is a relative difference in light intensity between the regions in direct contact to the substrate and the raised regions that are not in contact with the substrate. Due to van der Waals interactions between the polymer mask and substrate, the contact between the two is more intimate than that of a glass mask, which leads to a better resolution. By controlling the exposure dose, the regions of the substrate that are in contact with the polymer mask are exposed sufficiently while the regions of the substrate that do not have enough contact are not sufficiently exposed to be developed, thus a pattern is created. However, this technique also suffers the same limitation as in nanoimprint lithography since a more expensive lithography technique (e.g., EBL) must be used to create the master mask. Thus, there is a need for improved techniques to prepare such sub-micron structures. These and other needs are satisfied by the methods and compositions of the present disclosure.

Disclosed herein are articles comprising wrinkling structures. The wrinkling structures can be used as templates or masks for lithography purposes. In one aspect, the article can have periodic structures over large areas.

In one aspect, the articles disclosed herein are made from low-cost fabrication of periodic sub-micron structures over a large area, using a polymer mask, i.e. polydimethylsiloxane (PDMS).

Disclosed herein are articles comprising a wrinkling structure and a film of photosensitive material, wherein the wrinkling structure comprises a soft substrate and a first material, wherein the wrinkling structure has a first side and a second side, wherein at least a portion of the first side of the wrinkling structure contact at least a portion of the film of the photosensitive material.

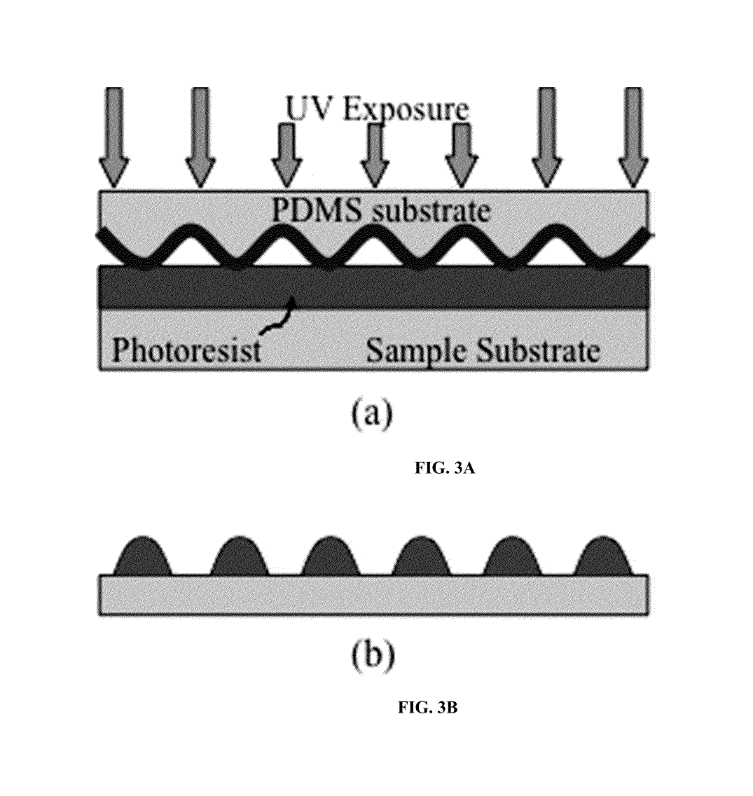

The wrinkling structure can be positioned in at least partially overlaying registration with the film of the photosensitive material. A non-limiting example of the foregoing is shown in FIG. 3A.

In one aspect, the photosensitive material can be a photoresist. The photosensitive material can be a positive or negative photosensitive material. For example, the negative photosensitive material. In another example, the photosensitive material can be a photosensitive material. Suitable negative photosensitive materials include, but are not limited to, KMPR 1000, ma-N 400, and ma-N 1400. Suitable positive photosensitive materials include, but are not limited to AZ3312, SPR 220, and S1800.

In one aspect, the photosensitive material can undergo a chemical reaction when exposed to wavelengths in the UV religion. For example, the photosensitive materials can undergo a chemical reaction when irradiated with a light emitting diode, mercury lamp, or UV lamp, such as a 365 nm UV lamp.

In one aspect, the film of the photosensitive material has a first and second side, wherein the first side of the wrinkling structure is in contact with at least a portion of the first side of the film of the photosensitive material, and wherein at least a portion of the second side of the film of the photosensitive material is in contact with an etchable substrate. In one aspect, the etchable substrate can be silicon or silicon dioxide. The contacting of the film of the photosensitive material and the etchable substrate can occur via an adhesion layers, such as a layer of hexamethyldisilazane (HMDS).

The film of the photosensitive material can be deposited onto the etchable via a variety of techniques, including spin-coating. In one aspect, the film of the photosensitive material has a thickness from 0.1 μm to 200 μm. For example, the film of the photosensitive material can have a thickness from 0.2 μm to 20 μm, from 0.2 μm to 10 μm, from 0.2 μm to 5 μm, or from 0.2 μm to 2 μm,

In one aspect, the first material comprises the first side of the wrinkling structure. The first material can be a film on the soft substrate. For example, the film of the first material can be deposited on the soft substrate via sputtering techniques known in the art. In one aspect, the first material can comprise gold, palladium, aluminum, silica, indium tin oxide, or a combination thereof For example, the first material can be gold/palladium or silica. In yet other aspects, the thin film can comprise one or more other materials not specifically recited herein, in lieu of or in combination with any one or more recited materials. The film of the first material can be less than 100 nm thick. For example, the film of the first material can be less than 100 nm, 80 nm, 60 nm, 40 nm, 20 nm, 10 nm, or 5 nm thick. In another example, the film of the first material can be from 0.5 nm to 100 nm thick, such as from 1 nm to 15 nm.

In one aspect, the soft subsrtance is transparent or translucent to light from a UV lamp, such as a 365 nm UV lamp. Said differently, the soft substrate does not absorb enough light to prevent the light from causing a chemical reaction in the photosensitive material. In one aspect, the soft substrate can be an elastomer. In one aspect, the soft substrate can be a polymer, for example, an elastomeric polymer. For example, the polymer can be or comprise, for example a co-polymer comprising, polydimethylsiloxane (PDMS).

In one aspect, the article can have periodic structures, such as a sinusoidal pattern, over large areas. The periodic structure can be the wrinkling structure or the photosensitive material or both. For example, the article can have periodic structures, such as a sinusoidal pattern, over an area from 1 cm² to 100 cm². In another example, the article can have periodic structures, such as a sinusoidal pattern, over an area from 10 cm² to 1000 cm².

In one aspect, the wrinkling structure has a sinusoidal pattern. The sinusoidal pattern can be observed if the wrinkling structure is observed in a cross section. In one aspect, the sinusoidal pattern has a periodicity of less than 20 μm. For example, the sinusoidal pattern can have a periodicity of less than 20 μm, 15 μm, 10 μm, 5 μm, 4 μm, 3 μm, 2 μm, 1 μm, 900 nm, 800 nm, 700 nm, 600 nm, 500 nm, 400 nm, 200 nm, 100 nm, or 50 nm. In another example, the sinusoidal pattern can have a periodicity from 50 nm to 20 μm, such as from 200 nm to 1 μm.

In another aspect, the wrinkling structures can be made from a thin film deposited on a stretched polydimethylsiloxane (PDMS) substrate. When the tension is released they form a buckling sinusoidal pattern on the surface. The PDMS substrates can then be used as masks in soft contact optical lithography, bypassing the need for an expensive lithographic process toward creating regular patterns on traditional masks. Pattern transfers can be conducted using, for example, a source of ultraviolet radiation, and more complex periodic structures can be fabricated through, for example, multiple exposures. In various aspects, ultraviolet radiation can be provided by an ultraviolet lamp, a light emitting diode, mercury lamp, or other devices capable of emitting ultraviolet radiation. Such pattern transfer techniques can be used on any surface, including curved and non-flat surfaces, enabling many new applications in microelectronics and biosensing, such as making periodic structures on target materials/structures as grating.

Sub-micron periodic patterns are heavily utilized in several applications, including memory, biological devices, optoelectronics, and solar cells based on nanostructures. Although techniques capable of fabricating sub-micron features have been developed and are well understood, including electron beam lithography (EBL), deep ultraviolet (UV) and interference lithography, scanning probe microscope (SPM) lithography, nanoimprint lithography, and self-assembly, these techniques offer their own set of prohibitive challenges. For example, EBL, deep UV lithography, and interference lithography require expensive equipment, while methods such as SPM lithography, along with EBL, have a serial write mechanism that makes large-area patterning costly and time-consuming. While nanoimprint lithography and self-assembly are relatively low cost and parallel processes, both still require an initial sub-micron patterning technique as described above, to create a master mold or masking pattern. Another method of fabricating large area periodic submicron structures, namely soft contact optical lithography has been explored recently. In this method, a polymer mask with a relief pattern is used to replace the traditional glass mask in photolithography. When light is exposed through the polymer mask onto the photoresist, there is a relative difference in light intensity between the regions in direct contact to the substrate and the raised regions that are not in contact with the substrate. Due to van der Waals interactions between the polymer mask and substrate, the contact between the two is more intimate than that of a glass mask, which leads to a better resolution. By controlling the exposure dose, the regions of the substrate that are in contact with the polymer mask are exposed sufficiently while the regions of the substrate that do not have enough contact are not sufficiently exposed to be developed, thus a pattern is created. However, this technique also suffers the same limitation as in nanoimprint lithography since a more expensive lithography technique (e.g., EBL) must be used to create the master mask.

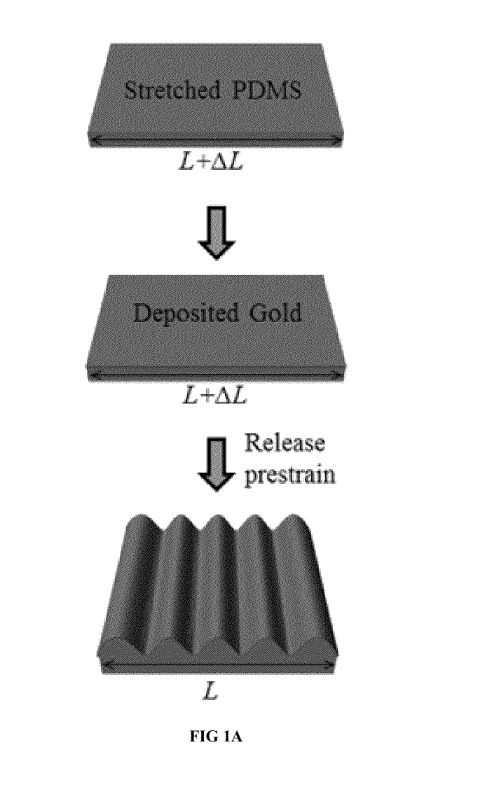

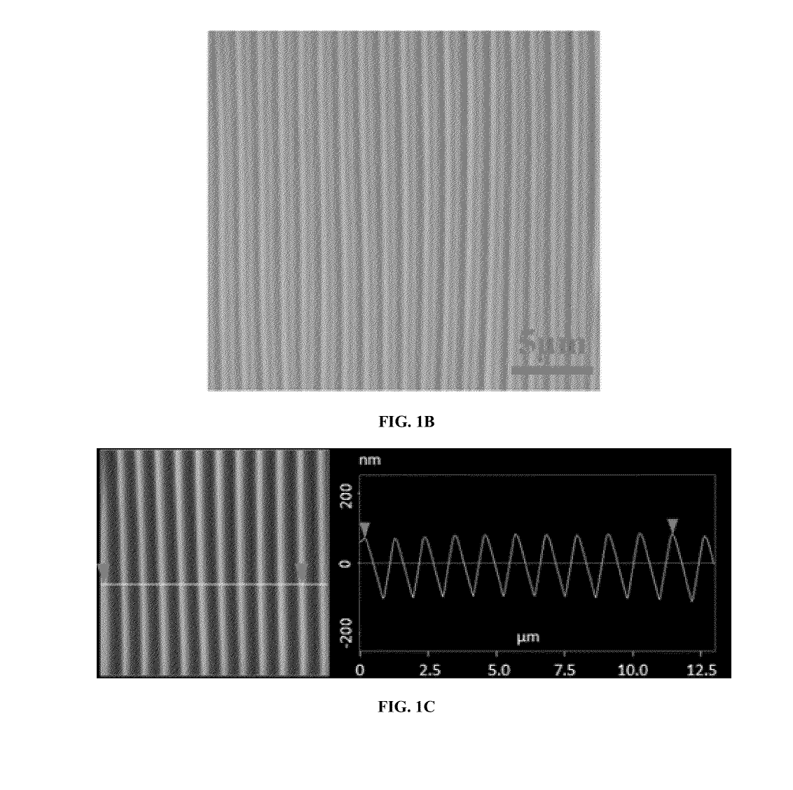

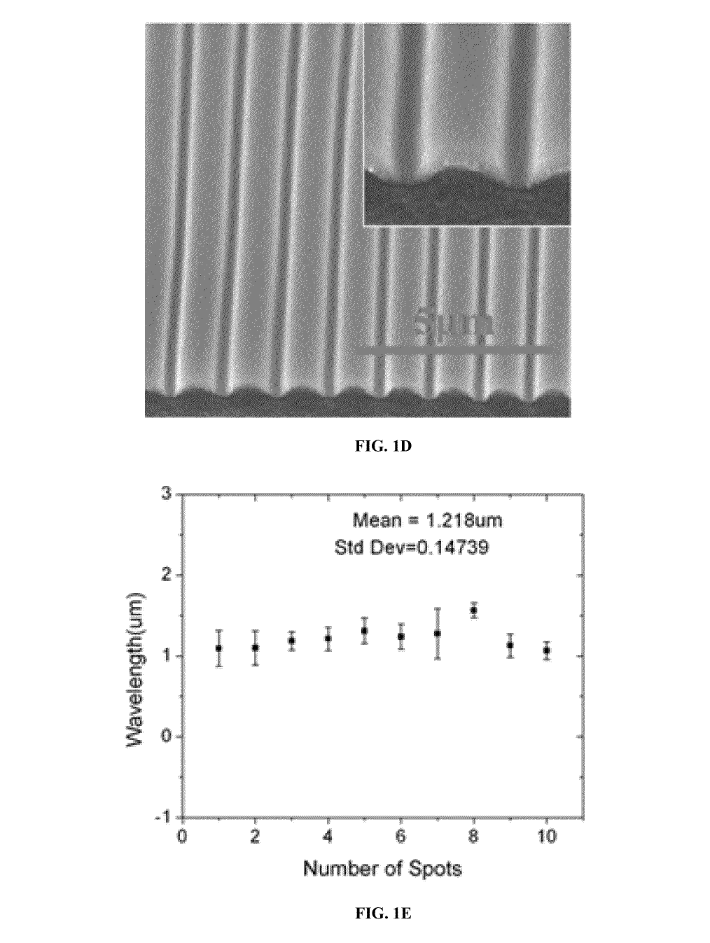

The present disclosure provides a low-cost approach toward creating the master mask using a polydimethylsiloxane (PDMS) polymer substrate decorated with a periodic buckling pattern on the surface. In addition, the methods of the present disclosure can utilize a simple UV lamp as the exposure source in place of a traditional mask aligner, reducing the cost and time-limiting factors of expensive equipment and slow processes and enabling the facile fabrication of large area submicron periodic structures. In one aspect, the present disclosure provides methods for fabricating buckled patterns atop PDMS materials using stiff buckled films on soft substrates. PDMS slabs can be prepared by mixing a polymer base with a curing agent (Sylgard 184, Dow Corning) and allowing the sample to cure for about 24 h at room temperature. In one aspect, the PDMS slab can be from about 1 mm to about 4 mm, for example, about 1, 2, 3, or 4 mm. In another aspect, the PDMS slab can be from about 1 mm to about 2 mm. In yet another aspect, the PDMS slab can be from about 3 mm to about 4 mm. In still other aspects, the PDMS slab can be less than or greater than any value specifically recited herein. In one aspect, the ratio of polymer base to curing agent can be any suitable ratio for the present invention. In another aspect, the ratio of polymer base to curing agent can be about a 10:1 ratio by weight. The PDMS slabs are then stretched (FIG. 1) with a strain of approximately 50%. In the stretched state, a thin layer of metal, for example, a few nanometers thick, is deposited onto the surface (FIG. 1), and/or a silica layer is formed on PDMS surface through oxygen plasma treatment. The PDMS is then relaxed and the metal layer contracts. Due to differing elastic moduli between the PDMS and metal, in addition to the fact that the metal layer itself is not stretched, the metal layer at the surface of the PDMS will buckle to form a sinusoidal pattern in order to release the total strain energy of the system.

Both metal and/or silica can be used to create a buckled surface layer. In an exemplary aspect, gold and palladium (Au/Pd) are sputtered onto pre-strained PDMS to form a patterned layer. For silica layer formation, the sample was exposed to oxygen plasma at 50 W for 30 s to form a hard silica-like layer at the surface that performs substantially the same function as the deposited metal layer.

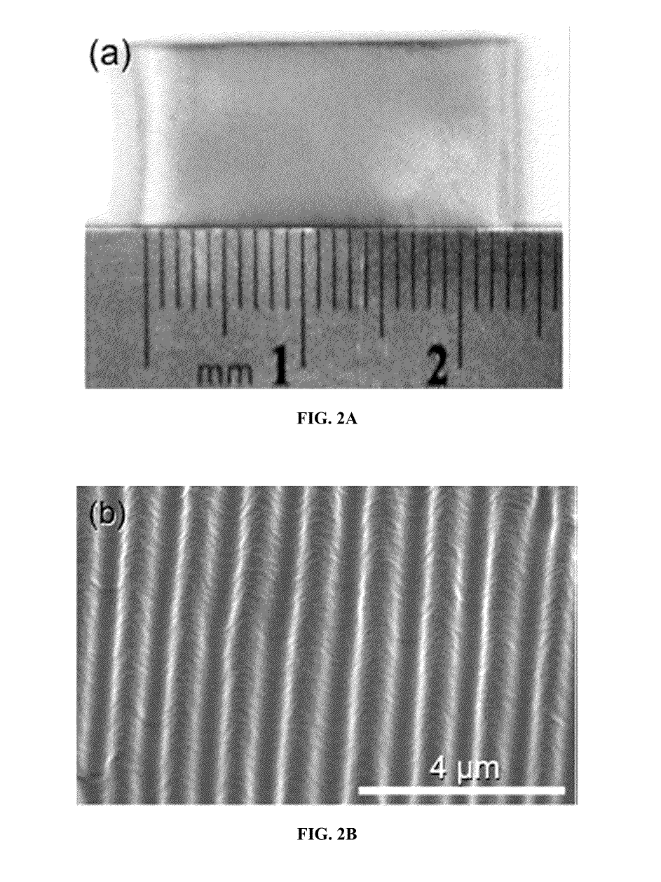

As illustrated in the optical image in FIG. 2(a), a mask of a few square centimeters can be fabricated using this very simple process without sophisticated and expensive photolithography or electron beam lithography equipment. The periodicity of the pattern is approximately 1.2 μm for a sample fabricated with 90 s of Au/Pd sputtering (FIG. 2(b)). It should be emphasized that this identical mask-making process can be scaled to fabricate much larger mask sizes on the order of tens of inches, for example, if a large mechanical stretching mechanism is used. The surface wrinkles on PDMS are then used as a soft contact photolithographic mask in a similar manner as a traditional glass mask is used in photolithography, as illustrated in FIG. 3. In such an aspect, a commercial mask aligner is not necessary for the pattern transfer because no or little micro-scale alignment is necessary. A simple monochromatic 365 nm UV lamp can be used in replacement of a mask aligner, which significantly reduces the cost of fabricating the nanowell pattern. In one aspect, pattern transfer can be accomplished on both glass and silicon substrates. In one aspect, glass slides were cleaved into approximately 6.25 cm² squares while the silicon substrates were cleaved into approximately 1 cm² samples. These sample sizes are chosen with respect to the size of the masks fabricated and can be scaled to larger sizes if a larger mask were desired. In one aspect, an AZ 3312 positive photoresist was used along with hexamethyldisilazane (HMDS) as an adhesion layer.

Both glass and silicon samples were prepared by spinning HMDS as an adhesion layer at 5000 rpm followed by AZ 3312 positive photoresist also at 5000 rpm. A subsequent pre-bake was conducted on a hot plate for 30 s at 100° C. Exposure dose calibrations were initially conducted using an EVG 620 mask aligner in order to identify the exposure dose range to create patterns using patterned PDMS mask. Subsequent exposures, including dual exposures, were used to fabricate nanopillar and nanowell arrays, and were conducted using a simple, standalone UV lamp with a central wavelength of 365 nm. The samples were placed approximately 10 cm below the lamp, at a power density of approximately 1.6 mW/cm². The samples were then developed in MIF 300 developer.

In various aspects, each of the chemicals and/or materials utilized herein for fabrication of a sub-micron structure is commercially available, and one of skill in the art, in possession of this disclosure, could readily select an appropriate chemical and/or material for use in preparing a desired structure. It should also be understood that any of the process conditions recited herein are intended to be exemplary and not limiting of the invention. Accordingly, one of skill in the art, in possession of this disclosure, could readily determine appropriate process conditions for use in preparing a desired sub-micron structure.

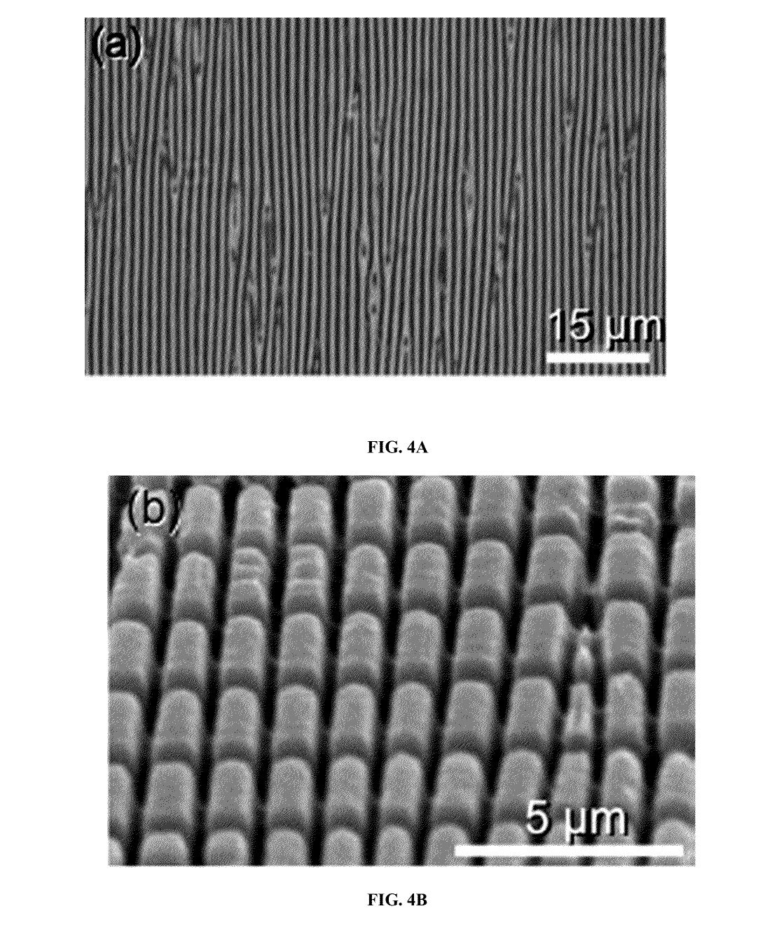

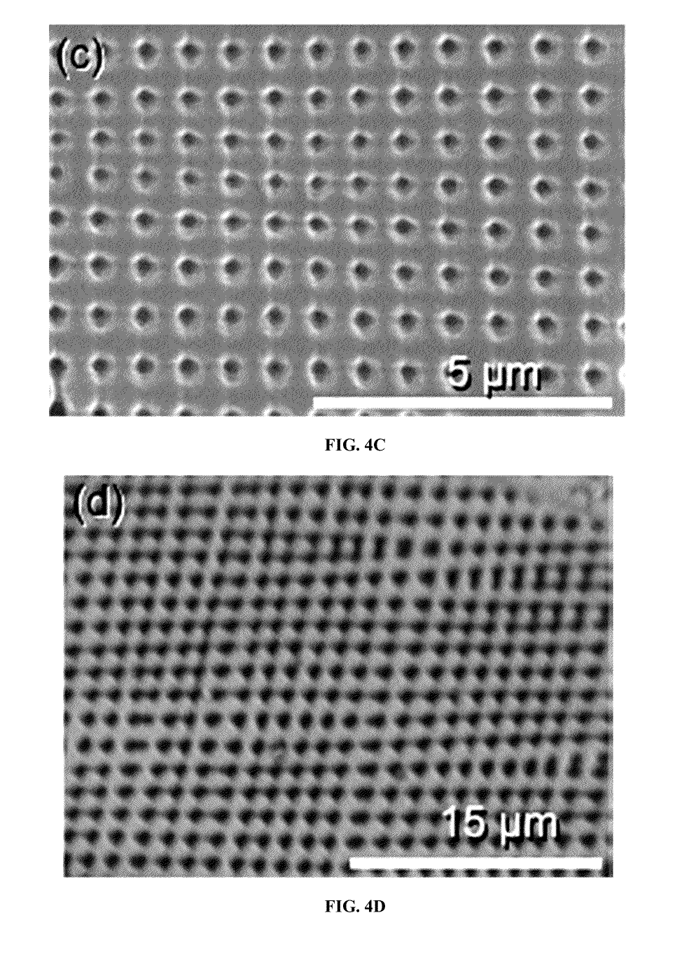

In one aspect, an optimal exposure dose for a single exposure was found to be approximately 80 mJ/cm² on average for a PDMS mask with a sputtered Au/Pd metal layer. It should also be understood that thicker metal layers can, in various aspects, require slightly higher dose requirements. In another aspect, exposure doses under about 60 mJ/cm², however, are unable to break the bonds in the photoresist, leading to no patterns being transferred. In another aspect, exposure doses above about 100 mJ/cm² can become overexposed, potentially developing away all initial photoresist. In such an aspect, overexposure can render the areas in intimate contact with the mask and those not in contact virtually indistinguishable. In yet another aspect, periodic structures can be transferred from a PDMS mask onto the photoresist layer under appropriate exposure conditions. FIG. 4(a) illustrates an optical image of a periodic line pattern created on a photoresist layer through such a transfer process.

In another aspect, the techniques described herein can be used to create two-dimensional patterns. For example, the use of two exposures can result in a variety of other regular two-dimensional patterns. In one aspect, after an initial exposure step, the mask can be rotated by 90° and then be subjected to a separate exposure. In one aspect, a periodic array of rectangular pillars, as illustrated in the scanning electron micrograph of FIG. 4(b), can be fabricated, when using two PDMS gratings with different periodicity at approximately 60 mJ/cm² per exposure. In such an aspect, the line pattern can be transferred to the substrate during both exposures. In another aspect, an array of 2D nanowells can be fabricated [FIG. 4(c)] at 40 mJ/cm² per exposure. In yet another aspect, the exposure dose from a single exposure is unable to break the bonds in the photoresist such that only points in direct contact with the PDMS mask during both exposures are exposed. In another aspect, the diameters of the wells can be approximately 300 nm with a periodicity of 725 nm. In such an aspect, these submicron features can be created without using traditional high resolution lithography tools. It should also be understood that the techniques described herein can be utilized to prepare sub-micron structures having sizes and/or periodicities other than those specifically recited herein, and the present invention is not intended to be limited to any particular value or range recited herein.

Masks can also be fabricated using oxygen plasma to create a thin surface buckling layer, as illustrated in FIG. 4(d). In one aspect, the total exposure dose required when using an oxygen plasma can be significantly reduced, for example, down to approximately 30 mJ, due to the increased transparent nature of the mask. In one aspect, more intimate contact between a mask and a glass and/or silicon substrate can lead to a larger yield of areas with strongly defined patterns. In still another aspect and while not wishing to be bound by theory, the surface plasmonic effect is not a key mechanism toward exposure when using an oxygen plasma. In another aspect, a silica layer formed by oxygen plasma treatment of the PDMS can be insulating. In such an aspect and while not wishing to be bound by theory, the mechanism for pattern transfer during exposure is not attributable to surface plasmonic enhancement of the electromagnetic field in the Au/Pd layer on PDMS mask.

Thus, in various aspects, a polymer mask can be been fabricated by the deposition of an Au/Pd metal layer and/or by the formation of a silica layer on a pre-strained sample of PDMS. In another aspect, such a technique can remove the need for an expensive mask writing process, such as electron beam lithography. In another aspect, various submicron patterns such as line gratings, rectangular pillars, and nanowell arrays can be fabricated utilized the techniques described herein by, for example, changing the number of exposures and the exposure dose. In yet another aspect, the techniques described herein can provide one or more advantages over conventional techniques, for example, using a monochromatic UV lamp instead of a commercial mask aligner, which can significantly decrease the cost of fabrication, the need for expensive equipment, and the need for time-consuming processes.

The wrinkling structures can be made from several techniques. One such method is described in Published US Application No. 2012/0212820, which is hereby incorporated by reference in its entirety. Disclosed herein is a grating manufacturing technique for the wrinkling structures, which can use buckled thin stiff film on soft substrates as a grating. The technique employs the use of a simple manufacturing process which only involves a mechanical straining process on soft substrates (e.g., polydimethylsiloxane (PDMS)), an oxygen plasma treatment step, and a routine metal (e.g., Au) deposition step. The simplicity of the fabrication steps allows the proposed technique to have significant cost advantage over other more conventional methods. This technique also promotes tunability of the wrinkling structures, i.e. the periodicity of the wrinkling structure can be altered. For example, the gratings, such as, PDMS/Au gratings, can be utilized as tunable strain sensors. The PDMS/Au grating is first contacted (or attached) to the sample of interest. Any change to the strain of the sample (thermally or mechanically induced) is imparted to the grating and changes its periodicity. The strain sensing mechanism relies on the detection of the variation in the diffraction angle of the laser beam shinning on the surface of the tunable grating. The variation in diffraction angle can then be related to the strain induced by the specimen of interest. The proposed tunable strain sensor or wrinkling structure and its detection mechanism are expected to have high strain sensitivity in capturing the strain variations within specimen.

Other techniques can also be used, such as two different conventional techniques can be used. The first method is the use of ruling engines in a diamond turning technique, where a high precision stage equipped with diamond tips is used in the manufacturing process. This method however, is a serial process, and is typically slow and expensive. The second method utilizes laser technology. Diffraction gratings made this way are called holographic gratings and have sinusoidal grooves. These techniques are rigid and not tunable.

Also disclosed are patterned photosensitive material made from the methods disclosed herein. In one aspect, the patterned photosensitive material can contact an etchable material.

### C. Methods

Also disclosed are methods of irradiating a photosensitive material.

In one aspect, the disclosed methods can make the structures of photosensitive material described elsewhere herein.

Disclosed herein is a method comprising a) providing article comprising a wrinkling structure and a film photosensitive material, wherein the wrinkling structure comprises a soft substrate and a first material, wherein the wrinkling structure has a first side and a second side, wherein the film photosensitive material has a first and second side, wherein at least a portion of the first side of the wrinkling structure contact at least a portion of the first side of the film of the photosensitive material; and irradiating second side of the wrinkling structure, thereby causing a chemical reaction in at least a portion of the photosensitive material.

In one aspect, the article is an article disclosed herein.

In one aspect, least a portion of the second side of the film of the photosensitive material is in contact with an etchable material. For example, the photosensitive material is in direct contact with an etchable material. In another example, the photosensitive material is in contact with an etchable material via an adhesive layer, such as a layer of hexamethyldisilazane (HMDS).

In one aspect, the chemical reaction in the photosensitive material changes the solubility of at least a portion of the photosensitive material. In one aspect, the chemical reaction in the photosensitive material makes the photosensitive material soluble in a solvent. In another aspect, the chemical reaction in the photosensitive material makes the photosensitive material insoluble in a solvent. Suitable photosensitive materials are described elsewhere herein.

In one aspect, the irradiating is done in the UV range (10 nm to 400 nm) or visible range (390 to 700 nm). For example, the irradiating can be done in the UV range. For example, the irradiating can be done in the range from 300 nm to 400 nm, such as, for example, 365 nm. In another example, the irradiating can be done in the visible range, such as, for example, between 400 nm and 420 nm, such as a 405 nm laser. The intensity and length of the irradiation is enough to cause a chemical reaction in film of the photosensitive material. In one aspect, the chemical reaction is through the whole thickness of the film at the portion where the irradiation is sufficiently intense to cause a chemical reaction.

In one aspect, the irradiating is performed with a UV lamp, a light emitting diode, or mercury lamp. For example, the irradiating is performed with a UV lamp, such as a 365 nm UV lamp.

In one aspect, the method further comprises removing a portion of the photosensitive material. This is also called developing the photosensitive material. During this process a portion of the photosensitive material is not removed. For example, a portion of the photosensitive material is contacting the etchable material after a portion of the photosensitive material has been removed.

In one aspect, the method further comprises subjecting the article to an etch process, thereby etching the etchable material. The etch process can be a wet or dry etch process. For example, the process can be a wet etch process. In another example, the process can be a dry etch process, such as a plasma etch process. Suitable plasma etch processes include reactive ion etching (RIE) and inductive coupled plasma etching (ICP).

In one aspect, the photosensitive material is removed after the etching step.

Also disclosed herein is an article comprising the photosensitive material and the etchable material produced by any of the methods disclosed herein.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

Several methods for preparing the compounds of this invention are illustrated in the following Examples. Starting materials and the requisite intermediates are in some cases are commercially available, or can be prepared according to literature procedures or as illustrated herein.

### a. Example 1

FIG. 1(a) illustrates the fabrication flow of the PDMS/Au grating. A polydimethylsiloxane (PDMS) elastomer (Sylgard 184, Dow Corning) was made by mixing the base component and the curing agent in a 10:1 ratio by weight, followed by de-gassing and curing at 80° C. for 3 hours. A slab of PDMS elastomer (0.1-1 mm thick) was mounted and elastically stretched by a home-made stage with designed uniaxial pre-strain. After being exposed to oxygen plasma (50 W) for 1 minute to enhance the adhesion, the pre-strained PDMS slab was sputter-coated with a gold (90%)/palladium (10%) (Au/Pd) alloy film of nanoscale thickness. The addition of palladium to gold increases its bonding strength, known as white gold. Due to the small proportion of palladium we will refer to the alloy as gold. Finally, the relaxation of the pre-strain in the PDMS substrates compresses the Au thin film, leading to the deformation and wrinkling in both the Au film and PDMS substrate surface in a sinusoidal pattern. This is a result of the minimization of the system's potential energy by the out-of-plane deformation. The wrinkling period, d, is determined by the mechanical properties of Au film and PDMS substrate, the pre-strain εₚᵣₑ, and the thickness of the gold film, as described previously [21]

$$d = {\frac{2 π {h}_{f}}{{( 1 + {ɛ}_{pre} ) [ 1 + \frac{5}{32} {ɛ}_{pre} ( 1 + {ɛ}_{pre} ) ]}^{1 / 3}} [ \frac{{E}_{f} ( 1 - {v}_{s}^{2} )}{3 {E}_{s} ( 1 - {v}_{f}^{2} )} ]}^{1 / 3} . \qquad ( 1 )$$

where h_{f} is the thickness of the Au film, E is Young's modulus and ν is Poisson's ratio. The subscripts “s” and “f” refer to the PDMS substrate and Au film, respectively. By varying the pre-strain εₚᵣₑ and the Au film thickness h_{f}, the buckling period d can be tuned with a broad range. In this work, the buckling period is in the order of micron or sub-micron range for the optimal grating efficiency for the visible light, which is employed for strain sensing application as discussed below.

FIG. 1(b) shows an optical microscopy image of a PDMS/Au grating fabricated by the above mentioned method, with h_{f}=10 nm, Sₚᵣₑ=15%, and the measured buckling period d=1.22 μm, which agrees well with the calculated value of 1.20 μm obtained from Eq. (1) when the following material parameters are used, E_{f}=80 GPa, Eₛ=2 MPa, h_{f}=10 nm, ν_{f}=0.3, and νₛ=0.4921. FIG. 1(c) shows the atomic force microscopy (AFM) image of the grating topography and a line-scan profile, which illustrates the uniformity of the buckling in a small area. FIG. 1(d) illustrates scanning electron microscopy (SEM) image of the continuous gold film along wave direction on PDMS. To examine the uniformity over a large area, the buckling periods were measured at ten different locations on an area of 100×100 μm² and the results are shown in FIG. 1(e). It was found that the buckling period is uniform over a large area.

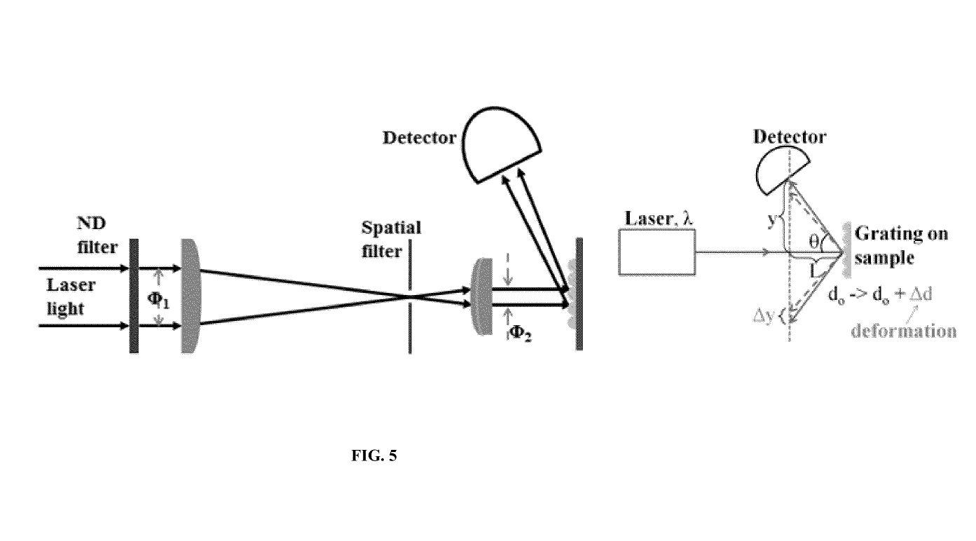

Optical setup for micro-strain sensing: A highly sensitive optical diffraction approach was developed to measure strain on the specimen of interest. By using a PDMS/Au grating attached to different specimens (for example, a silicon substrate), a minuscule change in strain within the specimen can be detected with a large change in displacement measured by the photo detector. This mechanism starts from the simple diffraction equation, d₀ sin θ=mλ, which relates the diffraction angle θ, initial grating period d₀, and laser source wavelength λ, m is the order of diffraction, when laser beam is normal to the grating surface. As shown in the inset of FIG. 5, the optical setup for strain measurement, a geometric relation, tan θ=y/L, relates the horizontal position L of the specimen and vertical position y of the photo detector.

When a strain is induced on the specimen through either mechanical or thermal means, the grating period changes from d₀ to d (=d₀+Δd) and leads to the change in diffraction angle θ by Δθ. Meanwhile, the change of θ results in the change of y by Δy, which linearly depends on Δd, as shown below,

$$Δ y = - \frac{λ L}{{{d}_{0}^{2} ( 1 - \frac{{m}^{2} {λ}^{2}}{{d}_{0}^{2}} )}^{3 / 2}} = Δ d = - \frac{λ L}{{{d}_{0} ( 1 - \frac{{m}^{2} {λ}^{2}}{{d}_{0}^{2}} )}^{3 / 2}} ɛ = - A ɛ . \qquad ( 2 )$$

where the strain (ε=Δd/d₀) of the specimen is related to Δy by the pre-factor A.

When L is in the order of 10 cm, and the buckling period d₀ and light wavelength λ, both in the order of sub-micron (mλ<d₀), the magnification factor A is approximately 1×10⁷ μm. To put this in perspective, one micro-strain (10⁻⁶) leads to a 10 μm change in the vertical position y of the photo detector, which is significantly easier to be measured. In addition, this magnification factor, A, can be further amplified by properly choosing a d₀ that approaches λ (Eq. (2)). This simple mechanism of magnification forms the basis of this highly sensitive strain measurement technique.

FIG. 5 illustrates the optical setup used in the micro-strain sensing. The light source was a 633 nm He—Ne laser with output power of 21 mW. The laser spot size had been reduced from 700 μm (Φ₁) to 200 μm (Φ₂) in diameter at the grating surface through the use of two optical lenses. In order to improve the signal to noise ratio, an optical chopper was placed before the series of optical lenses to synchronize with the optical detector. A 50/50 beam splitter generated a reference light signal which was fed into an auto-balanced photo detector. The photo detector compared the first order diffracted beam from the grating with the reference light to improve the signal-to-noise ratio for high sensitivity.

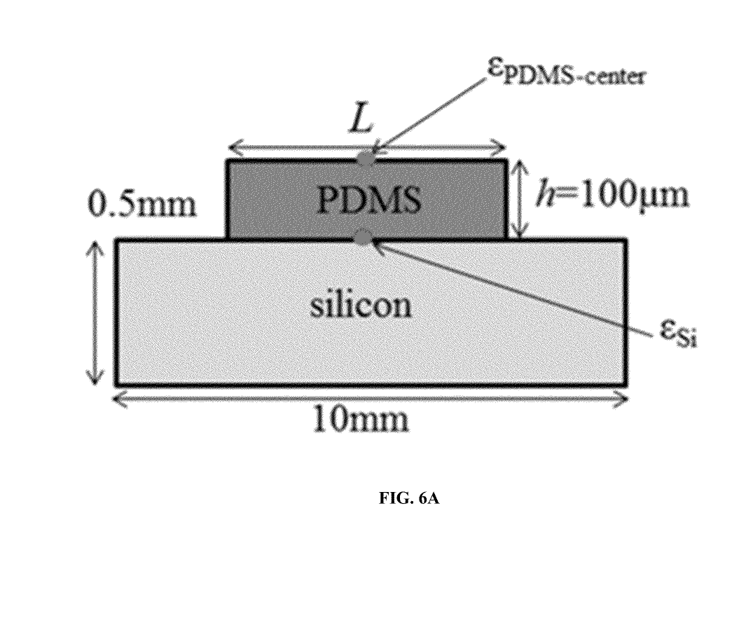

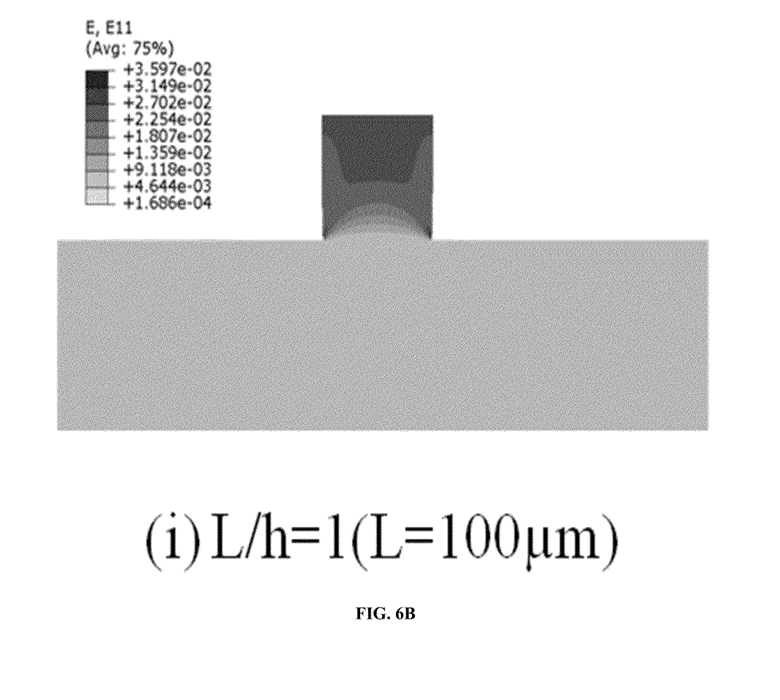

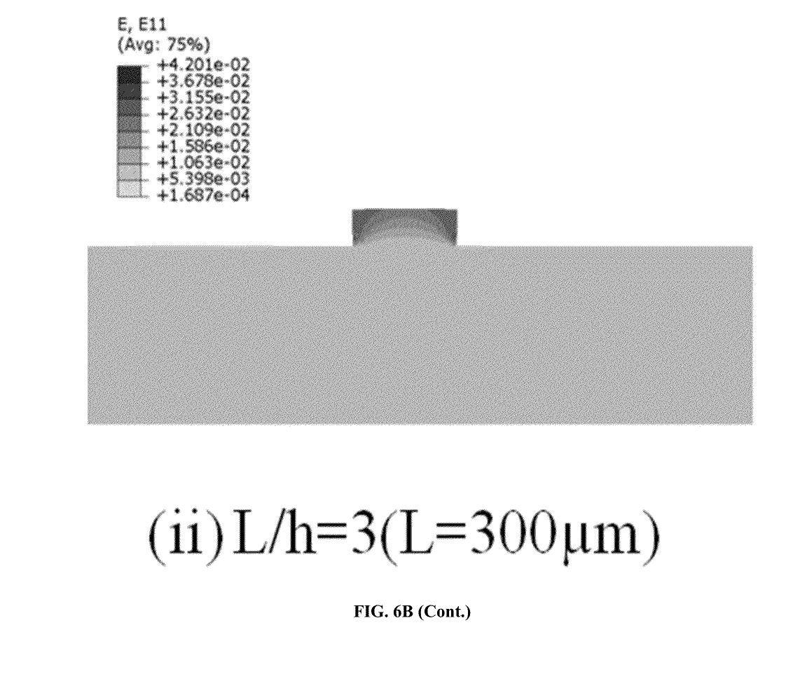

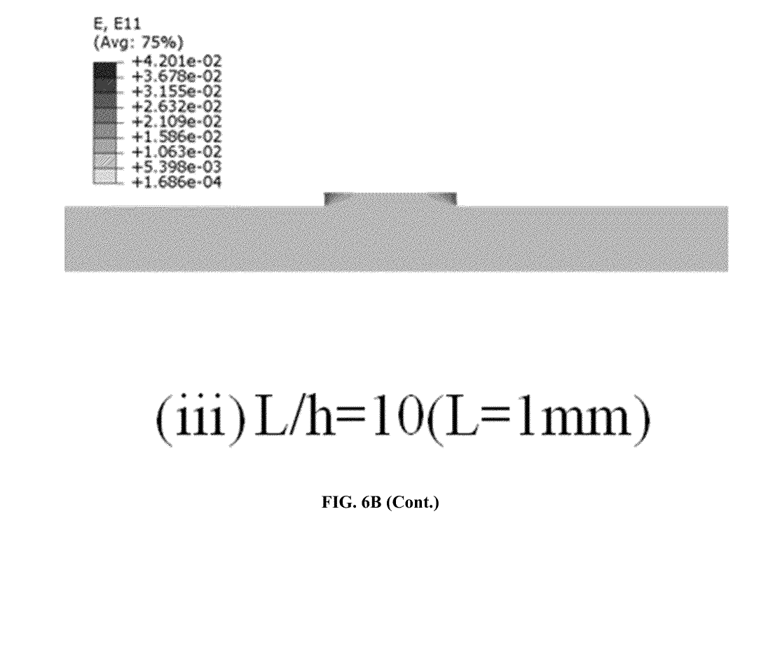

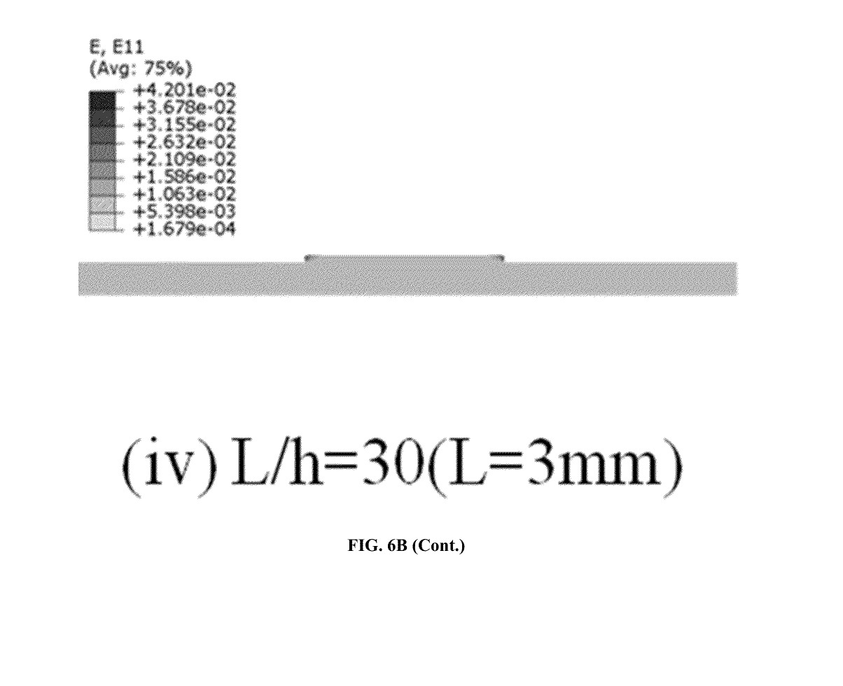

Results and discussion: PDMS effect: The change in measured diffraction angle directly relates to the change in periodicity of the PDMS/Au grating: One glaring question that needs to answered is whether or not the strain on the grating reflects the underlying strain on the specimen of interest. The commercial finite element package ABAQUS [26] was used to study this effect. FIG. 6(a) shows the model, including a PDMS grating with a thickness of 100 μm and length L on top of a 0.5 mm thick, 10 mm long silicon substrate. Thermal stress analysis is conducted by introducing a uniform temperature change ΔT. The PDMS and silicon substrate are modeled by 4-node plane strain temperature-displacement coupled elements (CPE4T). The PDMS-Si interface is treated as shared nodes. The bottom of the silicon substrate is confined. The top Au layer is not considered in the finite element analysis because its thickness is negligible (10 nm). The following material parameters are used in the analysis [27]: E_{PDMS}=2 MPa, ν_{PDMS}=0.5, α_{PDMS}=310×10⁻⁶/° C., E_{Si}=130 GPa, ν_{Si}=0.3 , α_{Si}=2.6×10⁻⁶/° C., ΔT=50° C., where α is the coefficient of thermal expansion (CTE).

Strain contours in the horizontal direction for different ratios of PDMS length and thickness are shown in FIG. 6(b). For L/h=1, the strain at the top surface of the center of the PDMS (ε_{PDMS}) is about two order of magnitude higher than the strain at the top of the silicon substrate (ε_{Si}). The explanation for this is that for a small L/h ratio, the constraint from the underlying silicon substrate is too weak. Therefore, the strain at the top of the PDMS grating, in this case, only reflects the PDMS itself and not the underlying silicon. As the L/h ratio increases, the constraint from the silicon substrate is increased and the strain at the top of the PDMS grating begins to resemble more and more like the strain of underlying silicon specimen of interest, as can be seen in FIG. 6(b). For an L/h ratio of 30, the strain of the PDMS grating is equal to the strain of the underlying silicon specimen of interest over 80% of the entire surface area of the PDMS grating. In this scenario, the detected strain ε_{PDMS} reflects the actual strain ε_{Si}.

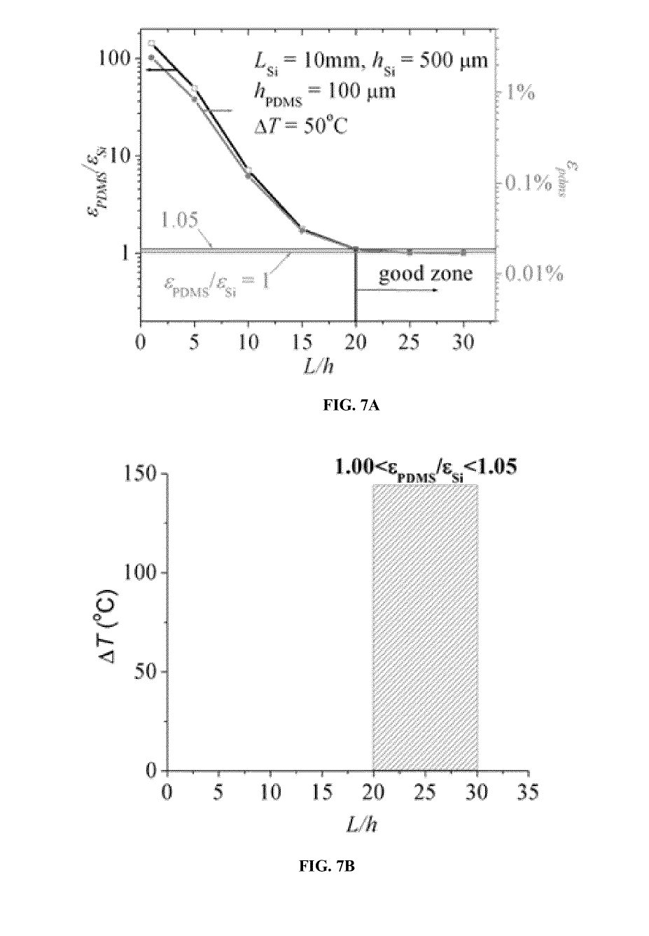

FIG. 7(a) shows the ratio of ε_{PDMS} and ε_{Si} as a function of L/h ratio for PDMS grating on Si substrate. It can be seen that when the L/h ratio exceeds a critical value of 20, the ε_{PDMS} reflects ε_{Si} with only a 5% error. FIG. 7(b) shows that this relation (i.e., L/h>20) holds for all temperature change due to the linearity of this relation. In fact, this analysis is likely to provide an upper bound of the L/h ratio because the CTE mismatch between silicon and PDMS is likely to be more severe than most conventional metals and polymers. However, note that for materials with a smaller CTE than silicon, such as, glass and other low CTE ceramics, the critical value for L/h ratio can be smaller than 20.

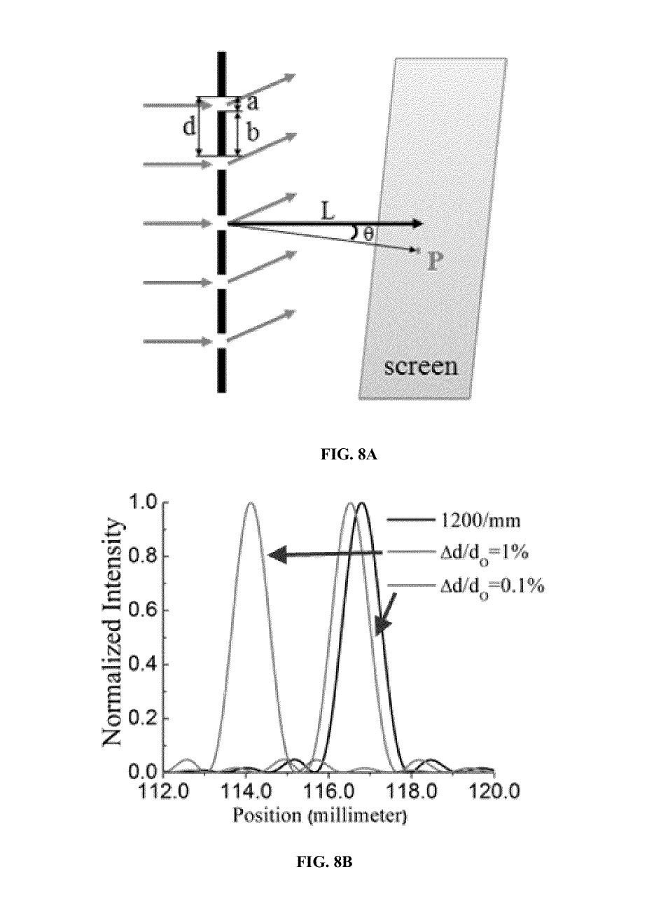

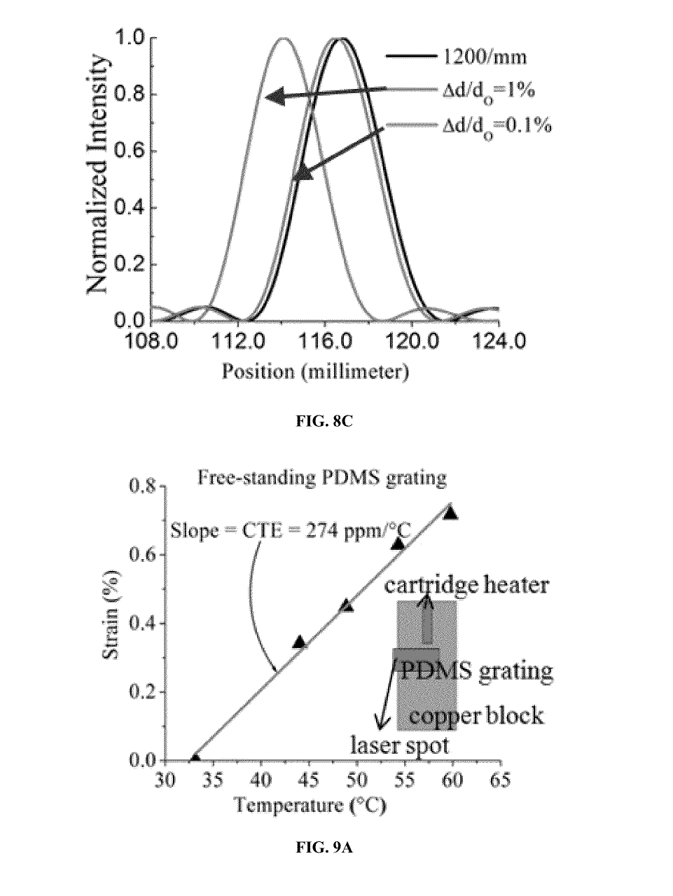

Simulation on diffracted laser beam intensity variation: Although the proposed method for strain measurement seems simple (FIG. 5), it is important to consider whether or not the shift in the peak position of the diffraction light due to a small strain can be differentiated. The laser spot size is an important parameter to consider. FIG. 8(a) shows the simulation model with a N-slit grating, where N is the number of slits with periodicity d(=a+b) for each slit. In other words, it is assumed that the laser light is shone on these N slits with a spot size of Nd. Within each slit, the opening and blocking region sizes are a and b, respectively. The detector is modeled as a screen. It is assumed that the light is incident and normal to the slits with a fixed ratio of d/a. The superposition of the waves from all the points within a single slit at point P, on the screen has an expression of,

$${U}_{1} = \int d {u}_{1} = {\int }_{0}^{a} \frac{{A}_{0}}{a} {e}^{- iω t} {e}^{i kxsin θ} d x , \qquad ( 3 )$$

where A₀ is the amplitude of the waves, k=2π/λ is the wave number of the incident light. The integration is over the opening area of the single slit.

At point P, the contribution from all N slits is expressed as the summation over all these N slits,

$$U = {A}_{0} \frac{sin α}{α} \frac{sin N β}{β} exp \{ i \frac{[ a + ( N - 1 ) ] sin θ}{λ} ω t \} , \qquad ( 4 )$$

where α=(πa/λ)sin θ, β=(πd/λ)sin θ.

Thus, the light intensity profile at point P is given by

$${I}_{P} = {U}^{2} = {{I}_{0} ( \frac{sin α}{α} )}^{2} {( \frac{sin N β}{β} )}^{2} . \qquad ( 5 )$$

where I₀=A₀² is the intensity of light impinging on the diffraction grating.

FIG. 8(b) shows the first order diffraction patterns with a laser spot size of 200 μm and grating to screen distance L=10 cm. The black line indicates the measurement when no strain is applied, while the red and green lines represent intensity profile when 1% and 0.1% strain applied, respectively. In this case, the laser wavelength is set to be 633 nm, the number of slits N is set to be 240, and the initial grating period is 833.3 nm (i.e., 1,200 lines/mm) FIG. 8(c) shows the same results as FIG. 8(b) but with a 50 μm laser spot size. It is clear that a smaller grating period variation leads to a smaller peak shift. This comparison suggests that a detector with high sensitivity is required to capture the localized strain variation with a very small laser spot size. Quantitative analysis indicating further reducing laser spot size to 10 μm and with N=12 for d=800 nm grating, a 0.1% strain will lead to light intensity change on the order of 10⁻⁴, well within the limit of the auto-balanced photo detector chosen in the experiment. The strain sensitivity in our detection scheme can be estimated. The auto-balanced photodetector used in our experiment can detect optical intensity variation on the order of 10^{'16}, therefore 1 nW intensity difference for 1 mW signal due to diffraction peak shift can be translated to a strain of 2.3×10⁻⁶ for a laser spot size of 200 μm from simulation and through Eq. (2).

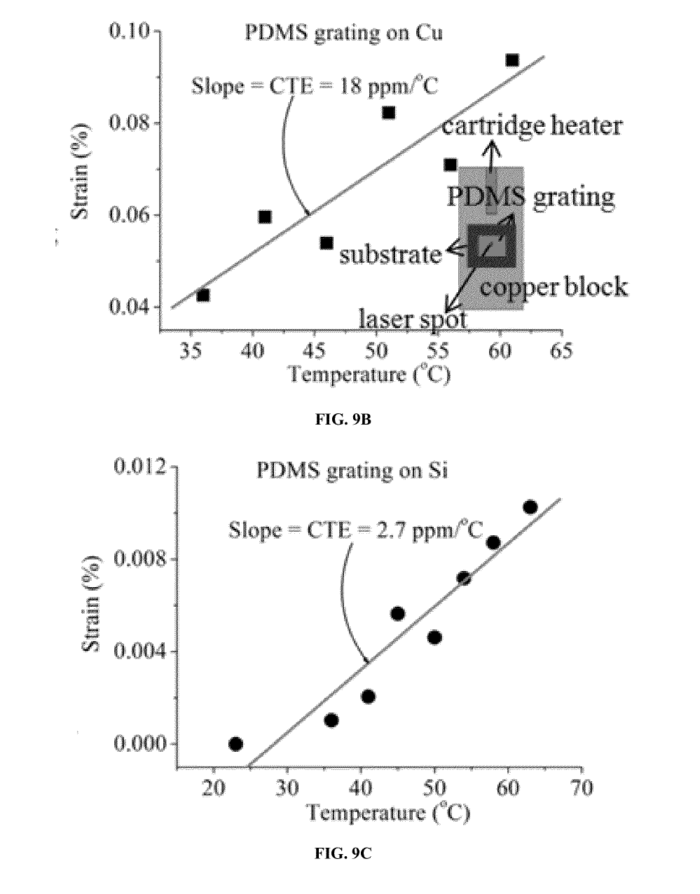

Benchmark of strain measurement: To verify the micro-strain sensing technique with tunable PDMS/Au grating proposed earlier, thermal strains of various materials, with differing coefficient-of-thermal-expansions (CTE) spanning 3 orders of magnitude were measured. PDMS/Au gratings are bonded on specimens that are heated up by a copper block, as shown in FIG. 9. A thermal couple is attached to the copper block to form a feedback system for the temperature control. In this system, the temperature reading on the specimen is calibrated to be within one degree of accuracy, and the temperature range for the strain measurement is between room temperature and 65° C. The laser spot size is 200 μm.

The first specimen is a freestanding PDMS grating, which is hanging over at the edge of the copper block, as shown in the inset schematic in FIG. 9(a). The focused laser spot is located just off the copper block to measure the thermal strain of the PDMS grating without constraints from the copper block. FIG. 9(a) shows the measured strain as a function of temperature for this freestanding PDMS grating, where a good linearity is observed. The CTE of PDMS, i.e., the slope of strain/temperature relation, is 274 ppm/° C. (part per million per degree Celsius), which agrees with the reference value of the CTE of PDMS, 265 ppm/° C., measured using commercial thermal-mechanical analysis tool Q400 from TA instruments, under expansion mode at 10 mN force.

The second specimen is a piece of copper sheet, on which the PDMS/Au grating is attached by a thin double-sided adhesive tape. The size of PDMS/Au grating has been chosen based on FIG. 7(a) to ensure the measured strain on top of the grating accurately reflects the strain of copper substrate. FIG. 9(b) shows the strain-temperature relation. The CTE of copper given by the slope is obtained as 18.2 ppm/° C., which is consistent with the CTE value of copper (17.5 ppm/° C.) [28]. Some of the data points in FIG. 9(b) are scattered compared to FIG. 9(a), which can be attributed to the bonding quality of the adhesive tape between copper and PDMS.

The last specimen is a Si substrate. The PDMS/Au grating can be firmly bonded to the Si substrate by treating the Si surface with oxygen plasma to form a SiO₂ bond between the PDMS and Si [29]. Si has a much lower CTE (2.6 ppm/° C.), compared to previous two specimen materials. The experimental data is plotted in FIG. 9(c), which gives an extracted CTE value of 2.73 ppm/° C., very close to the reference value of the Si CTE. The measured data here show much less fluctuation than the data from the PDMS bonded to copper as the result of much better bonding quality between Si and PDMS. The successful measurement of such small strain on Si on the order of 10⁻⁵, or a few nanometers displacement within 200 μm laser spot size, demonstrates the high strain sensitivity of this technique as a result of the unique grating fabrication technique and strain detection strategy. The results shown in FIG. 9 are representatives from many measurements we have performed, where several samples on each type of substrate were fabricated and measured, with each sample undergone a repeated temperature increase/decrease cycles, and the results show good repeatability.

PDMS tunable gratings fabricated through buckled film were used for micro-strain measurement of various materials. A highly sensitive optical setup optimized to amplify the small strain signal to the change in diffraction angle, orders of magnitude larger, was proposed. The applicability of the PDMS/Au grating to infer the strain of the underlying specimen of interest, require the L/h aspect ratio of the grating to greater than 20 for most practical purposes. In addition, the laser spot size was demonstrated to influence the measurement resolution significantly. Lastly, the thermal strain measurement on the free-standing PDMS grating as well as the PDMS grating bonded to copper and Si substrates agree well with the reference CTE values of PDMS, copper and Si, respectively. This technique is simple for very high strain sensitivity measurement, and its potential spatial scanning capability is also expected to complement the application boundaries of other in-plane strain measurement metrologies such as Moire Interferometry or digital image correlation (DIC) methods in terms of maximum strain gradient, and field-of-view of measurement. In addition, unlike conventional in-plane strain sensing metrologies, the proposed technique is expected to work for non-planar surface geometry, as well.

### b. Example 2

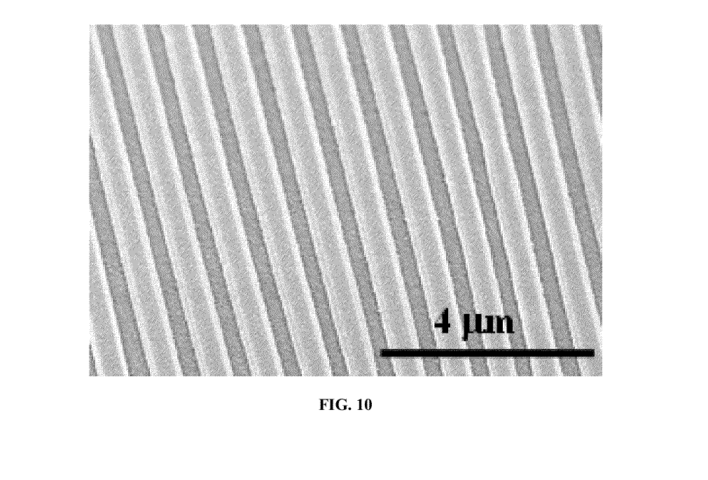

The methods disclosed herein have a high robustness. The direct fabrication of structures is not only fit for optically smooth planar surface but also rough surface as long as the surface roughness is less than 0.4 μm for complete photoresist coating. FIG. 10 shows the directly fabricated grating on an electron-bean evaporated copper surface (which is smooth). Such robustness can be used in the large chip packaging market. There, the sample surfaces are rather smooth and suitable for direct grating fabrication, as they are either planarized in the planar die geometry, or will be polished with the finest grain size of 0.1 μm in the cross-sectional geometry.

### c. Example 3

The structure shown in FIG. 4a was made as follows: The pattern was fabricated via the process shown in FIGS. 3a and 3b. The buckled PDMS substrate was pressed onto a glass slide coated with photoresist and subsequently exposed to approximately 80 mJ/cm² of UV light. After development, the pattern on the PDMS is transferred to the glass slide.

The structure shown in FIG. 4b was made as follows: The buckled PDMS substrate was pressed onto a silicon wafer coated with photoresist and subsequently exposed to approximately 60 mJ/cm² of UV light. Then, the PDMS was removed, rotated 90°, and then pressed back onto the substrate after which the sample was exposed to another dose of 60 mJ/cm² of UV light. After developing, the pattern seen in FIG. 4b was obtained.

The structures shown in FIGS. 4c and 4d were made as follows: The same fabrication method as in FIG. 4b, except the sample was only exposed to 40 mJ/cm² of light each time.

The key difference to create the different patterns in 4b and 4c and d was the different light exposure doses. Exposing 60 mJ/cm² of UV light was enough to expose and transfer the buckling pattern onto the substrate. So by exposing twice and 90° angles, it was possible to expose everything, leading to only the photoresist that had not been exposed to UV light during either of the exposures remaining. However, 40 mJ/cm² of UV light was not enough to expose the photoresist, so only the intersecting regions that had been exposed to UV light during both exposures got developed away, leading to the well patterns in the photoresist.

The structure shown in FIG. 10 was made as follows: a 100-nm-thick copper film was deposited on silicon wafer as a substrate for grating using e-beam evaporation and soft optical contact lithography is then applied on this copper substrate using PDMS wrinkling as photo masks. After developing sub-micron periodic pattern is transferred from pdms wrinkling to photoresist. 100-nm gold layer is then deposited on the substrate using e-beam evaporation. Photoresist is stripped off in acetone by lift-off and 100-nm-thick gold ribbons with sub-micron period are fabricated on copper substrate as a grating.

### REFERENCES

1. K. Efimenko, M. Rackaitis, E. Manias, A. Vaziri, L. Mahadevan, and J. Genzer, “Nested self-similar wrinkling patterns in skins,” Nat. Mater. 4, 293-297 (2005).

2. X. Y. Jiang, S. Takayama, X. P. Qian, E. Ostuni, H. K. Wu, N. Bowden, P. LeDuc, D. E. Ingber, and G. M. Whitesides, “Controlling mammalian cell spreading and cytoskeletal arrangement with conveniently fabricated continuous wavy features on poly(dimethylsiloxane),” Langmuir 18, 3273-3280 (2002).

3. P. Uttayarat, G. K. Toworfe, F. Dietrich, P. I. Lelkes, and R. J. Composto, “Topographic guidance of endothelial cells on silicone surfaces with micro- to nanogrooves: Orientation of actin filaments and focal adhesions,” J. Biomed. Mater. Res. A 75A, 668-680 (2005).

4. C. H. Lu, H. Mohwald, and A. Fery, “A lithography-free method for directed colloidal crystal assembly based on wrinkling,” Soft Matter 3, 1530-1536 (2007).

5. A. Schweikart and A. Fery, “Controlled wrinkling as a novel method for the fabrication of patterned surfaces,” Microchim. Acta 165, 249-263 (2009).

6. S. Wagner, S. P. Lacour, J. Jones, P.-h. I. Hsu, J. C. Sturm, T. Li, and Z. Suo, “Electronic skin: architecture and components,” Physica E Low Dimens Syst Nanostruct. 25, 326-334 (2004).

7. S. P. Lacour, S. Wagner, Z. Huang, and Z. Suo, “Stretchable gold conductors on elastomeric substrates,” Appl. Phys. Lett. 82, 2404-2406 (2003).

8. S. P. Lacour, J. Jones, Z. Suo, and S. Wagner, “Design and performance of thin metal film interconnects for skin-like electronic circuits,” IEEE Electr Device Lett. 25, 179-181 (2004).

9. S. P. Lacour, J. Jones, S. Wagner, T. Li, and Z. Suo, “Stretchable interconnects for elastic electronic surfaces,” Proc. IEEE 93, 1459-1467 (2005).

10. S. P. Lacour, S. Wagner, R. J. Narayan, T. Li, and Z. Suo, “Stiff subcircuit islands of diamondlike carbon for stretchable electronics,” J. Appl. Phys. 100, 014913 (2006).

11. C. Yu and H. Jiang, “Forming wrinkled stiff films on polymeric substrates at room temperature for stretchable interconnects applications,” Thin Solid Films 519, 818-822 (2010).

12. W. M. Choi, J. Song, D.-Y. Khang, H. Jiang, Y. Y. Huang, and J. A. Rogers, “Biaxially stretchable “wavy” silicon nanomembranes,” Nano Lett. 7, 1655-1663 (2007).

13. D.-Y. Khang, H. Jiang, Y. Huang, and J. A. Rogers, “A stretchable form of single-crystal silicon for high-performance electronics on rubber substrates,” Science 311, 208-212 (2006).

14. H. Q. Jiang, Y. G. Sun, J. A. Rogers, and Y. G. Huang, “Mechanics of precisely controlled thin film buckling on elastomeric substrate,” Appl. Phys. Lett. 90, 133119 (2007).

15. K. M. Choi and J. A. Rogers, “A photocurable poly (dimethylsiloxane) chemistry designed for soft lithographic molding and printing in the nanometer regime,” J. Am. Chem. Soc. 125, 4060-4061 (2003).

16. H. Jiang, D.-Y. Khang, J. Song, Y. Sun, Y. Huang, and J. A. Rogers, “Finite deformation mechanics in buckled thin films on compliant supports,” Proc. Natl. Acad. Sci. 104, 15607-15612 (2007).

17. C. Yu, C. Masarapu, J. Rong, B. Wei, and H. Jiang, “Stretchable Supercapacitors Based on Buckled Single-Walled Carbon-Nanotube Macrofilms,” Adv. Mater. 21, 4793-4797 (2009).

18. C. Yu, Z. Wang, H. Yu, and H. Jiang, “A stretchable temperature sensor based on elastically buckled thin film devices on elastomeric substrates,” Appl. Phys. Lett. 95, 141912 (2009).

19. C. M. Stafford, C. Harrison, K. L. Beers, A. Karim, E. J. Amis, M. R. Vanlandingham, H. C. Kim, W. Volksen, R. D. Miller, and E. E. Simonyi, “A buckling-based metrology for measuring the elastic moduli of polymeric thin films,” Nat. Mater. 3, 545-550 (2004).

20. J. L. Wilbur, R. J. Jackman, G. M. Whitesides, E. L. Cheung, L. K. Lee, and M. G. Prentiss, “Elastomeric optics,” Chem. Mater. 8, 1380-1385 (1996).

21. C. J. Yu, K. O'Brien, Y. H. Zhang, H. B. Yu, and H. Q. Jiang, “Tunable optical gratings based on buckled nanoscale thin films on transparent elastomeric substrates,” Appl. Phys. Lett. 96, 041111 (2010).

22. N. Bowden, S. Brittain, A. G. Evans, J. W. Hutchinson, and G. M. Whitesides, “Spontaneous formation of ordered structures in thin films of metals supported on an elastomeric polymer,” Nature 393, 146-149 (1998).

23. N. Bowden, W. T. S. Huck, K. E. Paul, and G. M. Whitesides, “The controlled formation of ordered, sinusoidal structures by plasma oxidation of an elastomeric polymer,” Appl. Phys. Lett. 75, 2557-2559 (1999).

24. J. S. Sharp and R. A. Jones, “Micro-buckling as a route towards surface patterning,” Adv. Mater. 14, 799 (2002).

25. H. Schmid, H. Wolf, R. Allenspach, H. Riel, S. Karg, B. Michel, and E. Delamarche, “Preparation of metallic films on elastomeric stamps and their application for contact processing and contact printing,” Adv. Funct. Mater. 13, 145-153 (2003).

26. A. U. Manual, “Version 6.5, Hibbitt, Karlsson and Sorensen,” Inc., Pawtucket, R.I. (2004).

27. R. Li, Y. Li, L. Chaofeng, J. Song, R. Saeidpouraza, B. Fang, Y. Zhong, P. M. Ferreira, J. A. Rogers, and Y. Huang, “Thermo-mechanical modeling of laser-driven non-contact transfer printing: two-dimensional analysis,” Soft Matter 8, 7122-7127 (2012).

28. C. S. Selvanayagam, J. H. Lau, X. Zhang, S. Seah, K. Vaidyanathan, and T. Chai, “Nonlinear thermal stress/strain analyses of copper filled TSV (through silicon via) and their flip-chip microbumps,” III Trans. Adv. Pack. 32, 720-728 (2009).

29. B. H. Jo, L. M. Van Lerberghe, K. M. Motsegood, and D. J. Beebe, “Three-dimensional micro-channel fabrication in polydimethylsiloxane (PDMS) elastomer,” J. Microelectromech. Syst. 9, 76-81 (2000).

U.S. Pat. No. 5,115,344

US Published Patent Application No. 2009/0310209

US Published Patent Application No. 2009/0310221

US Published Patent Application No. 2010/0149640

US Published Patent Application No. 2012/0212820

What is claimed is:

1. An article comprising a wrinkling structure and a film of photosensitive material, wherein the wrinkling structure comprises a soft substrate and a first material, wherein the wrinkling structure has a first side and a second side, wherein at least a portion of the first side of the wrinkling structure contact at least a portion of the film of the photosensitive material.

2. The article of claim 1, wherein the first material comprises the first side of the wrinkling structure.

3. The article of claim 1, wherein the film of the photosensitive material has a first and second side, wherein the first side of the wrinkling structure is in contact with at least a portion of the first side of the film of the photosensitive material, and wherein at least a portion of the second side of the film of the photosensitive material is in contact with an etchable substrate.

4. The article of claim 1, wherein the first material is a film on the soft substrate.

5. The article of claim 4, wherein the film of the first material is less than 100 nm thick.

6. The article of claim 1, wherein the soft substrate is an elastomer.

7. The article of claim 1, wherein the soft substrate comprises a polymer.

8. The article of claim 7, wherein the polymer comprises polydimethylsiloxane (PDMS).

9. The article of claim 1, wherein the first material comprises gold, palladium, silver, copper, chrome, titanium, tungsten, aluminum, silica, indium tin oxide, or a combination thereof

10. The article of claim 1, wherein the first material comprises gold/palladium, silica, or a combination thereof

11. The article of claim 1, wherein the wrinkling structure has a sinusoidal pattern.

12. The method of claim 11, wherein the sinusoidal pattern has a periodicity of less than 10 μm.

13. A method comprising
a) providing article comprising a wrinkling structure and a film photosensitive material, wherein the wrinkling structure comprises a soft substrate and a first material, wherein the wrinkling structure has a first side and a second side, wherein the film photosensitive material has a first and second side, wherein at least a portion of the first side of the wrinkling structure contact at least a portion of the first side of the film of the photosensitive material;
b) irradiating second side of the wrinkling structure, thereby causing a chemical reaction in at least a portion of the photosensitive material.

14. The method of claim 13, wherein at least a portion of the second side of the film of the photosensitive material is in contact with an etchable material.

15. The method of claim 13, wherein the first material comprises the first side of the wrinkling structure.

16. The method of claim 13, wherein the chemical reaction in the photosensitive material changes the solubility of at least a portion of the photosensitive material.

17. The method of claim 13, wherein the irradiating is performed with a UV lamp, a light emitting diode, or mercury lamp.

18. The method of claim 13, wherein the method further comprises removing a portion of the photosensitive material.

19. The method of claim 19, wherein the method further comprises subjecting the article to an etch process, thereby etching the etchable material.

20. An article comprising the photosensitive material contacting the etchable substrate produced by the method of claim 18.
